(19) United States
(12) Patent Application Publication
(10) Pub. No.: US 2011/0164766 A1
(43) Pub. Date: Jul. 7, 2011

(54) Ribbon loudspeaker module and amplifier therefore

(76) Inventor: Clive Thomas, Moreleta Park (ZA)

(21) Appl. No.: 13/062,699

(22) PCT Filed: Sep. 8, 2009
(86) PCT No.: PCT/AU09/01175

§ 371 Date: Mar. 8, 2011

(30) Foreign Application Priority Data
Sep. 11, 2008 (ZA) 2008/07841

(51) Int. Cl. H03F 99/00

(52) U.S. Cl. 381/120

(57) ABSTRACT

A ribbon loudspeaker module includes a ribbon element of electrically conductive material and having a resistance of less than 1Ω and a magnetic system arranged to create a magnetic field about the ribbon element. A buffer amplifier having an input is arranged to receive a loudspeaker drive signal from an audio power amplifier and an output arranged to drive the ribbon element directly. The ribbon loudspeaker module is preferably a low frequency module, designed to handle audio signals below 5 kHz, and preferably in the range 20 Hz to 3 kHz or a part thereof. The ribbon element may have a resistance of less than 0.5Ω, less than 0.2Ω and even as little as 0.15Ω or less.

### BACKGROUND OF THE INVENTION

THIS invention relates to an amplifier for use in a ribbon loudspeaker module, and to a ribbon loudspeaker module incorporating the amplifier.

Ribbon loudspeakers are well known, and generally utilise a ribbon comprising a strip of conductive material such as aluminium, suspended under tension in a magnetic field produced by an array of magnets. Current passed through the ribbon causes it to move relative to the magnetic system, generating sound.

At present, ribbon drive units are used fairly widely as tweeters, but full range ribbon loudspeakers are rare. A significant problem associated with generating low frequencies in ribbon loudspeakers arises due to the need for a bass ribbon driver to be physically large and robust. In order to couple the ribbon to the air effectively, to generate adequate sound pressure levels, the width of the ribbon needs to be relatively great, typically 30 mm or more. Also, the conductive material of the ribbon needs to be relatively thick to ensure sufficient robustness for large excursions. This leads to a low electrical resistance, which may be of the order of 1Ω or less. This poses a very difficult load for most audio amplifiers and has largely prevented full-range ribbon loudspeakers from becoming a mainstream solution.

Some solutions have been proposed for mitigating the low resistance of a bass ribbon driver. In particular, the use of a transformer can increase the effective impedance of the driver. However, high quality transformers are expensive and their use introduces undesirable phase shifts, non-linearity at high power, and other problems. Other proposals, such as the arrangement disclosed in U.S. Pat. No. 7,106,880 of Bengtsson, utilise a filter network comprising resistors, capacitors and inductors to feed the ribbon drive units. Series resistors are used to create a “passive current feeding” arrangement for the ribbon elements, and the use of transformers is also contemplated.

It is an object of the invention to provide an alternative ribbon loudspeaker arrangement.

### SUMMARY OF THE INVENTION

According to the invention there is provided a ribbon loudspeaker module comprising:
a ribbon element of electrically conductive material and having a resistance of less than 1Ω;
a magnetic system arranged to create a magnetic field about the ribbon element; and
a buffer amplifier having an input arranged to receive a loudspeaker drive signal from an audio power amplifier and an output arranged to drive the ribbon element directly.

The ribbon loudspeaker module is preferably a low frequency module, designed to handle audio signals below 5 kHz, and preferably in the range 20 Hz to 3 kHz or a part thereof.

The ribbon element may have a resistance of less than 0.5Ω, less than 0.2Ω and even as little as 0.15Ω or less.

The buffer amplifier preferably has unity gain or less than unity gain.

In a preferred embodiment the buffer amplifier has a class AB topology and an output stage which is connected directly to the ribbon element.

The buffer amplifier is preferably arranged to be fed by a power supply having a supply voltage that is lower than that of a conventional power supply for an audio amplifier by a factor related to the difference in load impedance between the ribbon element and a conventional loudspeaker drive unit.

Preferably, the buffer amplifier is designed to operate from a supply voltage which is no more than 70% of that of an associated suitable main audio amplifier driving the loudspeaker, preferably no more than 50%, and even more preferably no more than 30%.

Further according to the invention there is provided a full range ribbon loudspeaker comprising at least one ribbon loudspeaker module as defined above for low frequencies; at least one additional ribbon loudspeaker module comprising a conventional ribbon drive unit; and a crossover network.

Preferably the crossover network includes series capacitors in the signal path to each said additional ribbon loudspeaker module.

The buffer amplifier may include at least one series capacitor in its signal path, imparting a leading phase angle to the signal which matches a leading phase angle imparted to the signal by a series capacitor in the crossover of said at least one additional ribbon loudspeaker module.

The buffer amplifier is preferably incorporated into the structure or enclosure of the loudspeaker.

The invention extends to the buffer amplifier itself.

### BRIEF DESCRIPTION OF THE DRAWINGS

FIG. 1 is a simplified schematic diagram illustrating the concept of the present invention;

FIG. 2 is a schematic circuit diagram of a buffer amplifier for a ribbon loudspeaker drive unit according to the invention;

FIG. 3 is a schematic circuit diagram of a crossover network used at the input of the buffer amplifier of FIG. 3; and

FIG. 4 is a schematic overall diagram of a full range ribbon loudspeaker according to the invention, incorporating the buffer amplifier of FIG. 3 and the crossover network of FIG. 3.

### DESCRIPTION OF A PREFERRED EMBODIMENT

The invention relates to a ribbon loudspeaker module, and particularly to a bass ribbon driver for a full range loudspeaker system using only ribbon drivers. The bass ribbon driver is driven by an active low impedance buffer amplifier (having unity gain or slightly lower) in order to isolate the low impedance load of this driver from the main audio amplifier driving the loudspeaker as a whole.

The reproduction of higher frequencies, as required in an audio application, does not present a problem for a ribbon driver. Frequencies of 1 kHz and up are conventionally processed by ribbon treble drivers or tweeters from a number of manufacturers.

Midrange frequencies present a slightly more difficult problem which can however be solved simply by using a relatively longer ribbon driver than conventionally employed in a tweeter. Provided the midrange ribbon has a length of 1 m or more, producing frequencies of 500 Hz or even lower should not present a problem.

The design of a bass ribbon driver capable of producing low frequencies (of the order of 30 Hz or lower) is possible using a magnetic system that provides a high field strength and a relatively long ribbon (typically 6 m or more) but driving such a ribbon with an audio signal does present a problem.

The bass ribbon driver may be substantially as described in International patent application WO 2008/001190, for example.

In order to produce bass frequencies from such a ribbon driver, a number of constraints are placed on the design of the ribbon due to the physics of the problem.

Firstly, the width of the ribbon must be sufficient to propagate a bass waveform effectively. This implies a minimum ribbon width of approximately 30 mm or more for bass frequencies down to 30 Hz or lower.

Secondly, the thickness of the ribbon must be adequate to provide sufficient tensile strength and sufficient elasticity within the corrugated ribbon construction so as to avoid plastic deformation of the structure in use. For adequate amplitude in large rooms, this implies a thickness of 20 microns (0.02 mm) or more.

The combination of the above constraints, together with the most practical choice of metal for the ribbon, which is aluminium or an alloy thereof, yields a very low characteristic impedance for the ribbon, and specifically a very low resistance. The typical resistance for a 6 m serialized ribbon with 34 mm ribbon width and 25 micron thickness is approximately 0.15Ω.

Due to the requirement to drive the ribbon with the greatest fidelity possible, it is not desirable to use the conventional solution of matching this low impedance to an audio amplifier using an impedance matching transformer. The reason for this is that transformers by their very nature are resonant devices. As a result, bass frequencies at high currents cause both overtones and undertones (harmonics of the input waveform both higher and lower than the fundamental) which are unacceptable in audio reproduction using a ribbon driver. Aside from issues of audible distortion, the undertones cause instability at high amplitudes which severely limit the usability of the device.

The use of series resistors is also undesirable as it creates problems of heat dissipation and substantially lowers the efficiency of the loudspeaker.

A solution to the problem is to design a buffer amplifier (an amplifier with approximately unity gain) which is capable of driving a very low impedance bad with good fidelity. This present invention proposes coupling a very specific amplifier directly to the bass ribbon driver in order to accomplish the required impedance matching, thereby allowing any conventional amplifier to drive the bass ribbon load with ease.

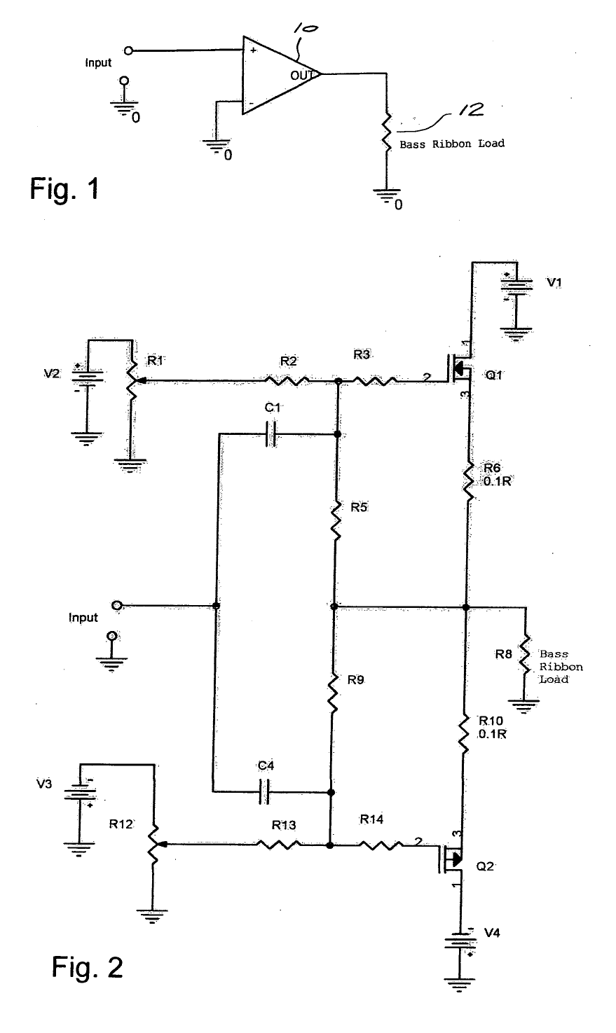

In concept the circuit is very simple, as illustrated in the conceptual schematic diagram of FIG. 1. An appropriate buffer amplifier 10 is coupled to the bass ribbon 12, receiving a drive signal from the output of the main amplifier in the conventional way. The problem encountered with the design of this amplifier is the requirement to drive a load with very low impedance (well below 1 ohm) which has a requirement of several amps of current (up to 6 A or 7 A in practical applications) in order to provide a high amplitude, low distortion audio output.

As a result of the combination of low impedance load and high current requirement, the most viable amplifier topology is class-AB. The reason for this is that the output of this topology is biased around 0V (ground), enabling direct coupling of the amplifier to the load, and the topology allows output devices to be paralleled if necessary. Of the other readily available topologies, class-A is not desirable as the output is at a DC offset, and a pure class-B design suffers from crossover distortion. Class-D is not viable due to the high current requirement.

The output devices must, for practical purposes, be selected from either MosFET (Metal oxide silicon field effect transistor) or bipolar transistors, these being the only readily available devices which yield adequate current coupled to adequate signal fidelity. In this application the choice between these is simple, as bipolar devices suffer from thermal runaway—when the temperature of the device rises, the gain of the device increases, thereby causing the generation of more heat, causing the gain to rise once more. This causes the device to fail rapidly under high current output conditions—an unacceptable limitation for this application. As a result, MosFET devices were chosen.

In a practical amplifier, the output current required must be provided by the output device (a MosFET, in this case). The problem which arises is that this device has a voltage drop across its drain and source, this being the difference between the supply voltage and the voltage across the load, and this voltage drop causes the generation of heat in the device directly proportional to the output current being generated. In a conventional medium powered audio amplifier with a 50V supply rail, there would be (typically) a 40V potential across each output device, which coupled to an output current requirement of, say, 6 A would result in 240 W of heat generated over all output devices. It is very difficult to dissipate this amount of heat—as a result the amplifier will typically start distorting at higher output levels, or the output devices may even fail due to exceeding operating temperature constraints.

A second problem is the issue of crossover distortion in class-AB topologies. Due to the amount of current required and the frequencies typical in this device, if the heat in the output devices is allowed to build up to the point where the gain of the device drops too much, the linear region of the device falls below the bias level and crossover distortion occurs. This is audible and unacceptable.

Both of these problems result from a single cause—heat generation in the output device. In order to solve the problem of heat generation, the dedicated nature of the amplifier allows lowering of the voltage supply rail to the MosFET output devices. As the low impedance bass ribbons to be coupled to this device only need a maximum voltage swing of about 20 Vrms, even for very high amplitude output, it is possible to lower the voltage supply to about 28V, thereby lowering the heat generated by the output devices to a manageable level. The output devices are also clamped to a large heat sink in order to dissipate the remaining heat generation.

The above supply voltage is just over half that of a typical medium power audio amplifier, and less than half that of a typical high power audio amplifier. In general, it is preferred that the buffer amplifier operate from a supply voltage which is no more than 70% of that of an associated suitable main audio amplifier driving the loudspeaker, preferably no more than 50%, and most preferably no more than 30%. It will be appreciated that where the main audio amplifier is a high power amplifier designed to drive loads with a nominal 4 to 8Ω impedance, it will have a relatively high voltage power supply compared to that needed to drive the very low impedance load presented by the bass ribbons, and the ratio of the power supply voltages of the main and buffer amplifiers will be dependent on their respective output power ratings and the impedance of the loads they are rated to drive.

The buffer amplifier circuit of FIG. 2 provides a solution to the problems encountered. The circuit is simple, with the only active components being Q1 and Q2, the MosFET output devices. In real-world applications for high amplitude audio output, it may be necessary to parallel these devices in order to achieve adequate current output without encountering device constraints on current delivery.

The power supplies for the output devices, V1 and V4, would typically be provided from a large capacitor bank (up to 0.1 Farad or more) in order to ensure that adequate current reserve exists for voltage levels to be maintained during high current demand at the load.

The bias for the output devices is generated and controlled using a completely passive bias circuit, with two well regulated DC power supplies V2 and V3 providing approximately 5V to variable resistors R1 and R12 which may be set to an appropriate bias level under static conditions. This bias is transferred to the input signal and hence to the gates of the output devices Q1 and Q2 via resistors R2 and R13. The choice of a passive design is due both to the simplicity of the design as well as the reliability and accuracy of the bias, resulting in the lowest possible output distortion.

The input signal is transferred to the gates of the MosFETs Q1 and Q2 via two capacitors C1 and C4. Capacitors are used here to isolate the amplifier from any DC offset at the output of the main audio amplifier being used to drive the buffer amplifier. In addition, the use of capacitors in this position of the circuit ensures that the bass ribbon signal is completely in phase with the signals provided to the midrange and treble ribbons of the loudspeaker, as these latter signals are filtered using serial capacitors, imparting a leading phase angle to the signal in each case. The employment of a coupling capacitor therefore fills the dual role of blocking DC as well as correcting the phase of the signal.

In order to balance the output current, especially if paralleled output devices are used, low value source resistors R6 and R10 are incorporated into the circuit which allow minor differences in the characteristic impedance of the MosFET devices to be equalized.

The actual bass ribbon module representing the load is depicted in FIG. 2 as a resistor R8. A ribbon driver is almost entirely resistive in nature and this is therefore an accurate simulation of the load.

As the inductance of midrange and treble ribbons of the kind in question and as described in the above mentioned International patent application is negligible (well below 1 pH) and the inductance of this form of bass ribbon is below levels which would require any special treatment (typically below 10 μH) it is not considered necessary to provide any circuit or mechanism to compensate for inductance. Even 10 μH of inductance implies an impedance of only 0.13Ω at 2 kHz, at or near the upper operating frequency of the bass ribbon, and it is therefore clear that no compensation is required.

The resistors R3 and R14 limit the frequency range of the output devices to within the audio range. The remaining components (resistors R5 and R9) allow the relative bias of the MosFET gates to be related to the ground level.

Due to the design constraints of the bass ribbon module, it is not desirable to allow high frequency signals to be processed by it. The main reason for this is the mass of the bass ribbon as compared with a suitable midrange or treble ribbon material—in the case of the bass ribbon, the foil used is typically 20 microns or more in thickness, as compared with 10 microns or less in the case of a good midrange ribbon. As a result, the transient response of the bass ribbon is not suitable for frequencies over 5 kHz, or even lower.

In order to ensure that the bass ribbon is not subjected to frequencies outside of the intended range, a filter circuit is employed before the buffer amplifier to restrict the bandwidth of signals processed and propagated to the bass ribbon.

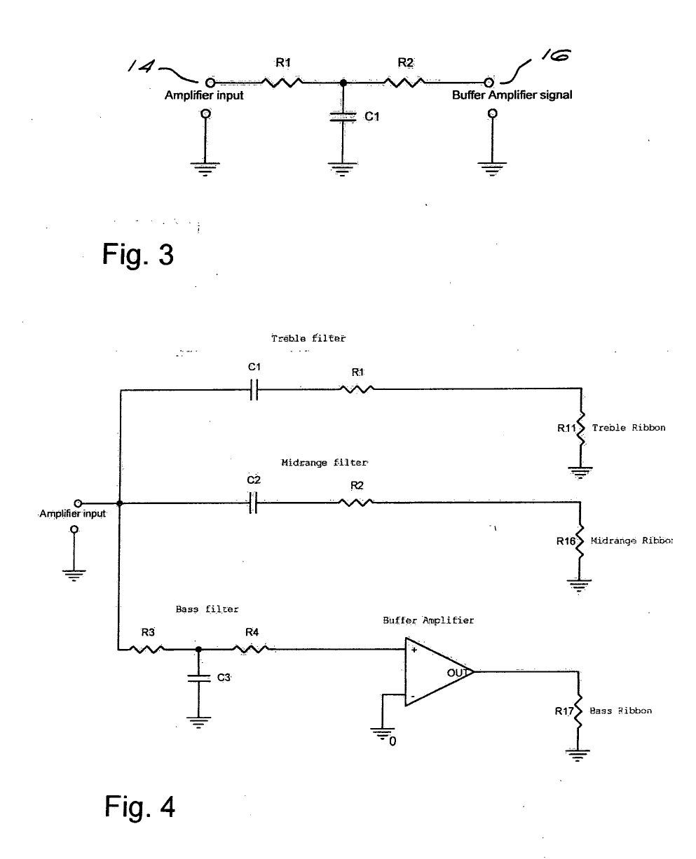

Conventionally, crossover networks in speakers use series inductors in order to filter out higher frequencies in the case of bass drivers. Due, however, to the very high impedance of the input of the buffer amplifier as described, compared with much lower loudspeaker impedances, it is possible to use a simple RC network to short higher frequencies to ground. Such a network is shown schematically in FIG. 3, and has an input 14 and an output 16, with two resistors R1 and R2 and a parallel capacitor C2.

The resistors R1 and R2 should be chosen so as to ensure that even when C1 becomes a very low impedance connection to ground, at high frequencies, this effective short circuit is isolated from the remainder of the filter network and the audio amplifier. Suitable values for these resistors may lie between 100Ω and 500Ω. The value of C1 would depend on the exact filter frequency desired, with typical values of 2 μF to 10 μF.

Assuming an overall loudspeaker implementation which consists of a bass ribbon, a midrange ribbon and a treble ribbon, the resistive nature of the drivers coupled to the wide bandwidth tolerance of this driver type allows for a very simple speaker implementation, as depicted schematically in FIG. 4.

In FIG. 4, three ribbon drive units R11, R16 and R17 (treble, midrange and bass) are shown as this is adequate to cover the audio spectrum with substantial overlap. Typical operating frequency ranges for these drivers would be as follows:
Bass ribbon: 20 Hz-3 kHz
Midrange ribbon: 400 Hz-15 kHz
Treble ribbon: 2 kHz-30 kHz

In order to filter the appropriate frequencies for each driver, a 6 dB per octave filter circuit is chosen. This allows the lowest possible phase distortion while adequately filtering undesirable frequencies from each driver.

The series capacitors in the filters for the treble and midrange ribbons and the parallel capacitor are chosen so as to provide the correct impedance given driver resistance and frequency range. Typical values would be:

C1=2 μF and C2=10 μF

The parallel capacitor C3 at the input of the buffer amplifier 10 functions as described above with reference to FIG. 3, and has a typical value of 8 μF.

The addition of resistors in the filter networks for the treble and midrange ribbons allow disparities of amplitude to be equalized with respect to the bass ribbon, so the resistors R1 and R2 would be chosen depending on relative efficiencies of the ribbon drivers and individual room acoustic considerations. Typical values would be between 1 ohm and 20Ω for of these resistors.

It is important to note that no inductors or transformers are used in the described buffer amplifier circuit. Both these devices exhibit significant tendency to resonate, and as a result are highly undesirable in this form of Circuit.

The result of the use of the buffer amplifier as described above is that the load seen by the audio amplifier driving the full range ribbon loudspeaker is relatively benign and undemanding, making it possible for a relatively modestly powered amplifier to drive the loudspeaker successfully. The buffer amplifier is preferably incorporated into the structure or enclosure of the loudspeaker, and a user of the loudspeaker can simply connect his/her audio amplifier to the input terminals of the loudspeaker as usual, with no special operating procedure being called for.

What is claimed is:

1. A ribbon loudspeaker module comprising:
a ribbon element of electrically conductive material and having a resistance of less than 1Ω;
a magnetic system arranged to create a magnetic field about the ribbon element; and
a buffer amplifier having an input arranged to receive a loudspeaker drive signal from an audio power amplifier and an output arranged to drive the ribbon element directly.

2. A ribbon loudspeaker module according to claim 1 wherein the module is a low frequency module, designed to handle audio signals below 5 kHz.

3. A ribbon loudspeaker module according to claim 2 wherein the module is designed to handle audio signals in the range 20 Hz to 3 kHz or a part thereof.

4. A ribbon loudspeaker module according to claim 1 wherein the ribbon element has a resistance of between 0.5Ω and 0.15Ω.

5. A ribbon loudspeaker according to claim 1 wherein the buffer amplifier has unity gain or less than unity gain.

6. A ribbon loudspeaker module according claim 1 wherein the buffer amplifier has a class AB topology and an output stage which is connected directly to the ribbon element.

7. A ribbon loudspeaker module according to claim 1 wherein the buffer amplifier is arranged to be fed by a power supply having
a supply voltage that is lower than that of a conventional power supply for an audio amplifier by a factor related to the difference in load impedance between the ribbon element and a conventional loudspeaker drive unit.

8. A ribbon loudspeaker module according to claim 1 wherein the buffer amplifier is designed to operate from a supply voltage which is no more than 70% of that of an associated suitable main audio amplifier driving the loudspeaker.

9. A ribbon loudspeaker module according to claim 8 wherein the buffer amplifier is designed to operate from a supply voltage which is between 50% and 30% of that of an associated suitable main audio amplifier driving the loudspeaker.

10. A ribbon loudspeaker incorporating a ribbon loudspeaker module according to claim 1 for low frequencies; at least one additional ribbon loudspeaker module comprising a conventional ribbon drive unit; and
a crossover network.

11. A ribbon loudspeaker according to claim 10 wherein the crossover network includes series capacitors in the signal path to each said additional ribbon loudspeaker module.

12. A ribbon loudspeaker according to claim 10 wherein the buffer amplifier includes at least one series capacitor in its signal path, imparting a leading phase angle to the signal which matches a leading phase angle imparted to the signal by a series capacitor in the crossover of said at least one additional ribbon loudspeaker module.

13. A buffer amplifier for a ribbon loudspeaker according to claim 10.
